(19) United States
(12) Patent Application Publication
(10) Pub. No.: US 2024/0093407 A1
(43) Pub. Date: Mar. 21, 2024

(54) SYSTEMS AND METHODS FOR DISASSEMBLING TWO-DIMENSIONAL VAN DER WAALS CRYSTALS INTO MACROSCOPIC MONOLAYERS AND REASSEMBLING INTO ARTIFICIAL LATTICES

(71) Applicant: THE TRUSTEES OF COLUMBIA UNIVERSITY IN THE CITY OF NEW YORK, New York, NY (US)

(72) Inventors: Fang Liu, New York, NY (US); Xiaoyang Zhu, New York, NY (US); James Hone, New York, NY (US); Sang Hoon Chae, New York, NY (US)

(73) Assignee: THE TRUSTEES OF COLUMBIA UNIVERSITY IN THE CITY OF NEW YORK, New York, NY (US)

(21) Appl. No.: 18/522,460

(22) Filed: Nov. 29, 2023

Related U.S. Application Data
(62) Division of application No. 17/105,105, filed on Nov. 25, 2020, now Pat. No. 11,866,847.
(60) Provisional application No. 62/963,839, filed on Jan. 21, 2020.
(60) Provisional application No. 62/944,753, filed on Dec. 6, 2019.

(51) Int. Cl. C30B 33/00; B32B 7/02; B32B 18/00; B32B 37/00; B32B 37/18; B32B 43/00; C23C 14/16; C23C 14/30; C30B 29/46; C30B 29/68

(52) U.S. Cl. CPC C30B 33/00; B32B 7/02; B32B 18/00; B32B 37/025; B32B 37/18; B32B 43/006; C23C 14/16; C23C 14/30; C30B 29/46; C30B 29/68; B32B 2315/02; C01G 41/00

(57) ABSTRACT

Systems and methods for generating one or more single crystal monolayers from two-dimensional van der Waals crystals are disclosed herein. Example methods include providing a bulk material including a plurality of van der Waals crystal layers, and exfoliating one or more single crystal monolayers of van der Waals crystal from the bulk material by applying a flexible and flat metal tape to a surface of the bulk material. In certain embodiments, the one or more single crystal monolayers can be assembled into an artificial lattice. The present disclosure also provides techniques for manufacturing flexible and flat metal tape for generating one or more single crystal monolayers from two-dimensional van der Waals crystals. The present disclosure also provides compositions for creating a macroscopic artificial lattice. In certain embodiments, the composition can include two or more macroscopic single crystal monolayers adapted from a bulk van der Waals crystal, where the single crystal monolayers are configured for assembly into an artificial lattice based on one or more properties.

### CROSS REFERENCE TO RELATED APPLICATION

This application is a Divisional of United States patent application Ser. No. 17/105,105, filed Nov. 25, 2020, now allowed, which claims priority to U.S. Provisional Application Serial No. 62/963,839, filed Jan. 21, 2020 and U.S. Provisional Application Serial No. 62/944,753, filed Dec. 6, 2019, each of which is incorporated by reference herein.

### STATEMENT REGARDING FEDERALLY SPONSORED RESEARCH

This invention was made with government support under grant numbers DMR-1420634 and DMR-1809680 awarded by the National Science Foundation, and grant number DE-SC00014664 awarded by the Department of Energy. The government has certain rights in the invention.

### BACKGROUND

Certain techniques for disassembling two-dimensional van der Waals crystals into macroscopic monolayers can be limited based on material quality, scalability, and size. For example, liquid phase exfoliation can be scalable but generate small sizes and poor quality. Chemical vapor deposition can be scalable but yield a high defect density. Mechanical exfoliation can produce high quality monolayers but at a low yield.

Accordingly, there exists a need for a high throughput technique for disassembling two-dimensional van der Waals crystals into high quality macroscopic monolayers.

### SUMMARY

Systems and methods for generating one or more single crystal monolayers from two-dimensional van der Waals crystals are disclosed herein.

Example methods include providing a bulk material including a plurality of van der Waals crystal layers, and exfoliating one or more single crystal monolayers of van der Waals crystal from the bulk material by applying a flexible and flat metal tape to a surface of the bulk material. The flexible and flat metal tape can have a surface root-mean-square roughness of less than about 2 nm. In certain embodiments, the flexible and flat metal tape can have a surface root-mean-square roughness of less than about 1 nm.

In certain embodiments of the present disclosure, the metal can be an air-stable metal, including coinage metals. For example, the metal can be Gold, Silver, Platinum, Palladium, Coper, Nickel, and/or Chromium.

In certain embodiments, the one or more single crystal monolayers can be assembled into an artificial lattice.

In certain embodiments, the exfoliating can include pressing the flexible and flat metal tape on to a surface of the bulk material and removing the flexible and flat metal tape off the surface to form a single crystal monolayer on the metal surface. In certain embodiments, the flexible and flat metal tape can include a thermal release tape having a layer including a soluble protection layer and a metal layer, where the removing further includes heating the tape, dissolving the protection layer in water, and dissolving the metal layer in an etchant solution.

The present disclosure also provides techniques for manufacturing flexible and flat metal tape for generating one or more single crystal monolayers from two-dimensional van der Waals crystals. An example method includes forming a layer of metal on an ultra-flat wafer, depositing a soluble polymer on the metal layer, and removing the metal layer and the polymer layer from the ultra-flat wafer.

In certain embodiments, the forming can include a metal layer having a surface root-mean-square roughness of less than about 2 nm. In certain embodiments, the forming can include a metal layer having a surface root-mean-square roughness of less than about 1 nm. In certain embodiments, the forming can include a metal layer having a surface root-mean-square roughness in the range of about 0.3 to about 0.5 nm. For example, the metal can be Gold, Silver, Platinum, Palladium, Coper, Nickel, and/or Chromium.

The ultra-flat wafer can be selected from a silicon wafer, a germanium wafer, a mica wafer, a single crystal semiconductor wafer, and a super-polished surface such as fused silica or glass.

In certain embodiments, the depositing includes coating the metal layer with the polymer. For example, the coating can be spin-coating.

In certain embodiments, the protection layer includes a soluble polymer. For example, the protection layer can be a water-soluble polyvinylpyrrolidone or an organic solvent-soluble polypropylene carbonate or polycarbonate or polycaprolactone polymer.

The present disclosure also provides compositions for creating a macroscopic artificial lattice. In certain embodiments, the composition can include two or more macroscopic single crystal monolayers adapted from bulk van der Waals crystals, where the single crystal monolayers are configured for assembly into an artificial lattice based on one or more properties. In certain embodiments, the one or more properties can include nonlinear optical properties.

In certain embodiments of the present disclosure, a first of the two or more macroscopic single crystal monolayers can have an orientation difference from a second of the two or more macroscopic single crystal monolayers, where the first and single crystal monolayers are adapted for reassembly into an artificial lattice. In certain embodiments, the orientation difference can be about 180 degrees. In certain embodiments, a first of the two or more macroscopic single crystal monolayers and a second of the two or more macroscopic single crystal monolayers are configured to create one of a single crystal heterobilayer or a single crystal heteromultilayer.

The accompanying drawings, which are incorporated and constitute part of this disclosure, illustrate embodiments of the present disclosure.

### BRIEF DESCRIPTION OF THE DRAWINGS

FIGS. 1A-1J illustrate an example layer-by-layer exfoliation procedure of a bulk van der Waals crystal in accordance with certain embodiments of the present disclosure;

FIGS. 2A-2C illustrate disassembly of a van der Waals crystal into single crystal monolayers in accordance with certain embodiments of the present disclosure;

FIGS. 3A-3F are optical images of single crystal monolayers and heterobilayers exfoliated from the metal tape methods in accordance with certain embodiments of the present disclosure;

FIG. 4 is an atomic force microscopy image of a MoS2 monolayer on a SiO₂/Si substrate in accordance with certain embodiments of the present disclosure;

FIGS. 5A-5G illustrate a comparison of photoluminescence spectra and intensity distributions of single crystal monolayers in accordance with certain embodiments of the present disclosure;

FIG. 6 illustrates UV-Vis spectra of the single crystal monolayers prepared from metal tape exfoliation on fused silica substrates in accordance with certain embodiments of the present disclosure;

FIGS. 7A-7B illustrate second-harmonic generation intensity of macroscopic MoSe₂ artificial lattices in accordance with certain embodiments of the present disclosure;

FIGS. 8A-8B illustrate second-harmonic generation intensity of macroscopic MoS₂ artificial lattices in accordance with certain embodiments of the present disclosure;

FIGS. 9A-9D illustrate simulations of second-harmonic generation intensity enhancement of macroscopic artificial lattice in accordance with certain embodiments of the present disclosure;

FIGS. 10A-10C illustrate a macroscopic MoSe₂/WSe₂ heterobilayer in accordance with certain embodiments of the present disclosure;

FIG. 11 illustrates second-harmonic generation intensity of the MoSe₂/WSe₂ heterobilayer as a function of the rotation angle of crystal with respect to light polarization in accordance with certain embodiments of the present disclosure;

FIG. 12 is an atomic force microscopy image of a MoSe₂/WSe₂ heterobilayer prepared by the metal tape exfoliation method on a SiO₂/Si substrate in accordance with certain embodiments of the present disclosure;

Throughout the drawings, the same reference numerals and characters, unless otherwise stated, are used to denote like features, elements, components or portions of the illustrated embodiments. Moreover, while the present disclosure will now be described in detail with reference to the FIGS., it is done so in connection with the illustrative embodiments.

### DETAILED DESCRIPTION

Techniques for disassembling two-dimensional van der Waals (vdW) crystals into macroscopic monolayers and reassembling into artificial lattices are disclosed herein.

The disclosed techniques can achieve high throughput disassembly of 2D vdW crystals layer-by-layer into single crystal monolayers, with near unity yield. The techniques disclosed herein can work for a range of vdW materials and generate monolayers with macroscopic dimensions comparable to the sizes of the bulk crystals, shown here for mm to cm lateral dimensions.

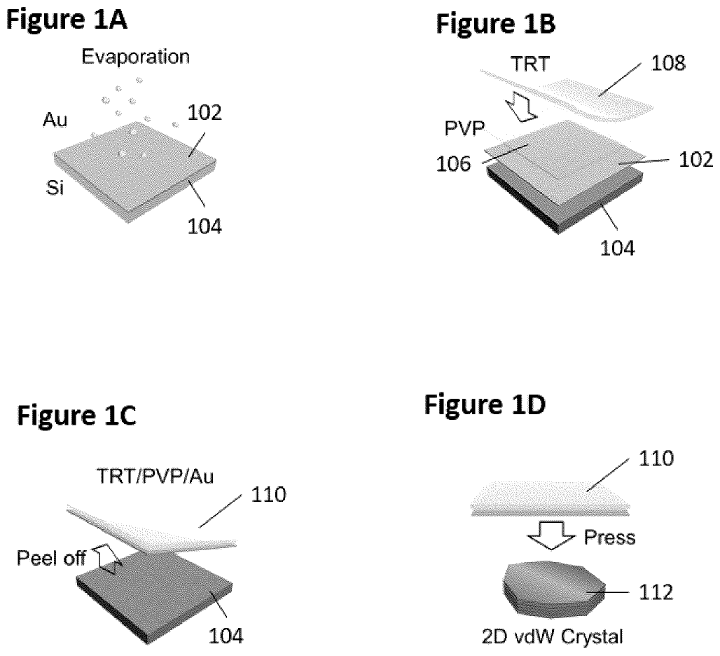

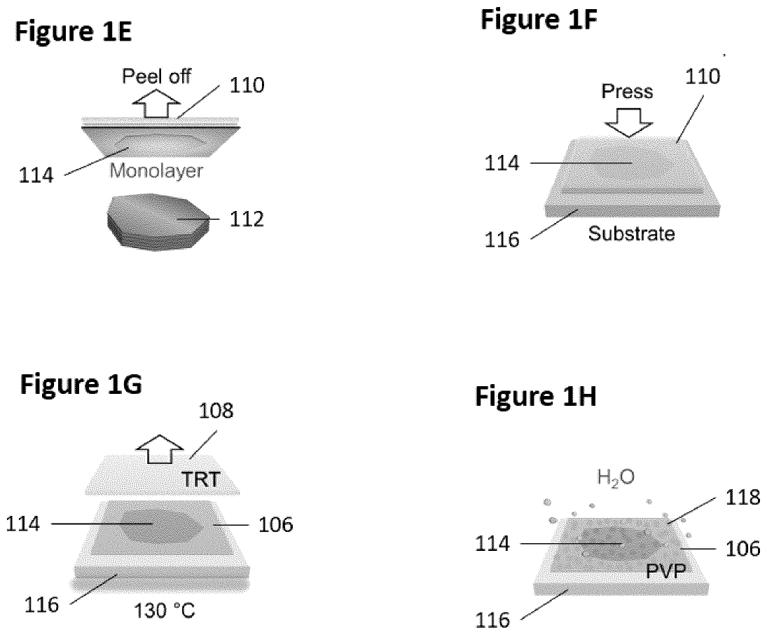

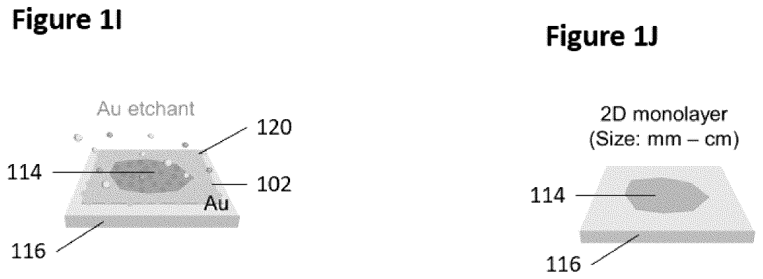

As schematically shown in FIGS. 1A-1J, a bulk vdW crystal can be exfoliated layer-by-layer. A flexible and flat metal tape can be achieved with a template stripping technique as shown in FIGS. 1A-1C. For example, the flexible and flat metal tape can include a thermal release tape (“TRT”) 108 having a layer including a soluble protection layer 106 and a metal layer 104. The metal tape can be suitably flat when a surface root-mean-square roughness of a side of the metal layer 106 opposite the soluble protection layer 104 is less than about 2 nm. In certain embodiments, the surface root-mean-square roughness of the side of the metal layer 106 opposite the soluble protection layer 104 can be less than about 1 nm. In certain embodiments, the surface root-mean-square roughness of the side of the metal layer 106 opposite the soluble protection layer 104 can be in the range of about 0.3 to about 0.5 nm. The metal tape can be suitably flexible, for example, when the tensile strength is about 30 kg/mm², and Young's modulus is about 5000 kg/mm².

As shown in FIG. 1A, the metal layer 102 can be deposited on an ultra-flat wafer 104. The ultra-flat wafer can be, for example, between 500 μm and 1 mm thick. The metal layer 102 can be an air-stable metal, including coinage metals. For example, the metal layer 102 can be Gold, Silver, Platinum, Palladium, Coper, Nickel, and/or Chromium. When implemented in inert environments, such as a glovebox or vacuum, the metal layer 102 can be Tin or Zinc.

The ultra-flat wafer 104 can be a silicon wafer, a germanium wafer, a mica wafer, a single crystal semiconductor wafer, and a super-polished surface such as fused silica or glass. As shown in FIG. 1B, the soluble protection layer 106 can be coated to the surface of the metal layer 102. The soluble protection layer 106 can be a polymer, such as water-soluble polyvinylpyrrolidone or organic solvent-soluble polypropylene carbonate or polycarbonate or polycaprolactone polymer.

As shown in FIG. 1C, the thermal release tape 108 can strip the soluble protection layer 106 and the metal layer 102 off the ultra-flat silicon wafer 104 to obtain the flexible and flat metal tape 110. The exposed metal surface 102 is templated by the flat substrate with roughness on the A scale. The flexible and flat metal tape allows intimate and uniform vdW contact between the metal and the 2D vdW crystal surface, exfoliating a complete monolayer, which can be transferred onto the desired substrate. For example, intimate and uniform vdW contact occurs when the interfacial roughness between the metal and the 2D vdW crystal surface is less than about 2 nm. In certain embodiments, the interfacial roughness between the metal and the 2D vdW crystal surface can be less than about 1 nm. In certain embodiments, the interfacial roughness between the metal and the 2D vdW crystal surface can be in the range of about 0.3 to about 0.5 nm.

FIG. 1D illustrates the flexible and flat metal tape 110 being pressed on to the surface of a bulk vdW crystal 112. The flexible and flat metal tape 110 can peel a monolayer 114 off the bulk vdW crystal 112 as in FIG. 1E, and the monolayer 114 can be transferred onto a substrate 116 as in FIG. 1F. As shown in FIG. 1G, the thermal release tape 108 can be removed with heat. For example, thermal release tape 108 can be removed at between about 100° C. and 140° C. The soluble protection layer 106 can be dissolved in water 118 or an organic solvent as in FIG. 1H, and the metal layer 102 can be dissolved in an etchant solution 120 as in FIG. 1I. As shown in FIG. 1J, the single crystal monolayer 114 with macroscopic dimensions can be obtained. For example, after removing the thermal release tape, washing off the PVP layer, and etching of gold with a mild etchant solution (I₂/I⁻), a monolayer with macroscopic dimension (typically mm to cm) can be obtained.

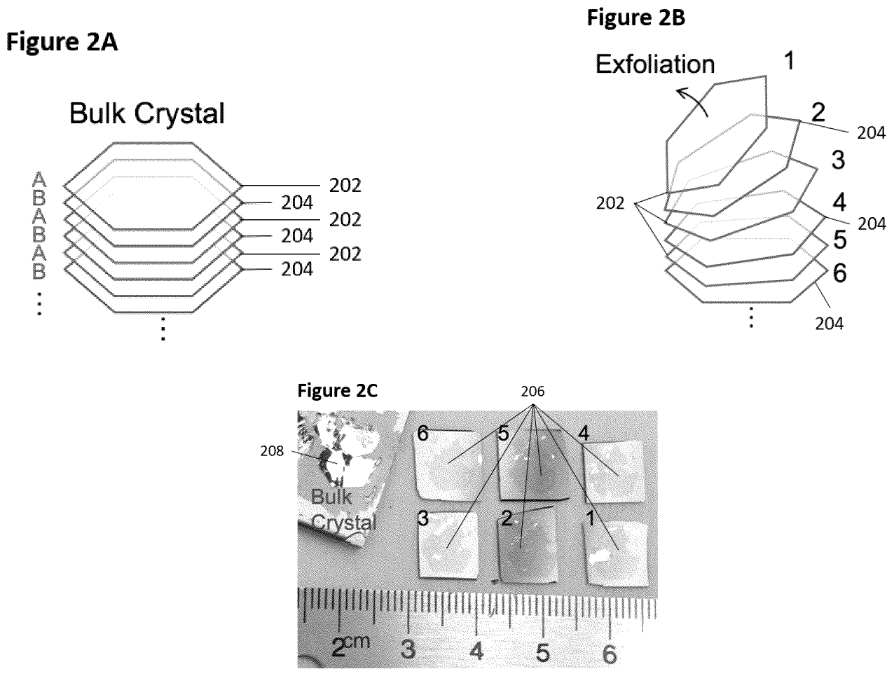

As illustrated in FIGS. 2A-2B, the layer-by-layer exfoliation technique can yield even layers 202 and odd layers 204 with a difference in crystallographic orientations. As illustrated for WSe₂ in FIG. 2C, the strong adhesion of gold to TMDCs can repeatedly generate complete single crystal monolayers 206, each adopting the shape of the entire surface of a bulk crystal 208. The yield of exfoliation, expressed as the percentage of monolayer area picked up from the contacted bulk crystal surface, can be close to unity.

This technique can be applied to a broad range of vdW crystals, as demonstrated for single crystal TMDCs monolayers (e.g., WS₂, MoS₂, WSe₂, MoSe₂, and ReS₂) on various substrates, such as SiO₂/Si, fused silica, and sapphire.

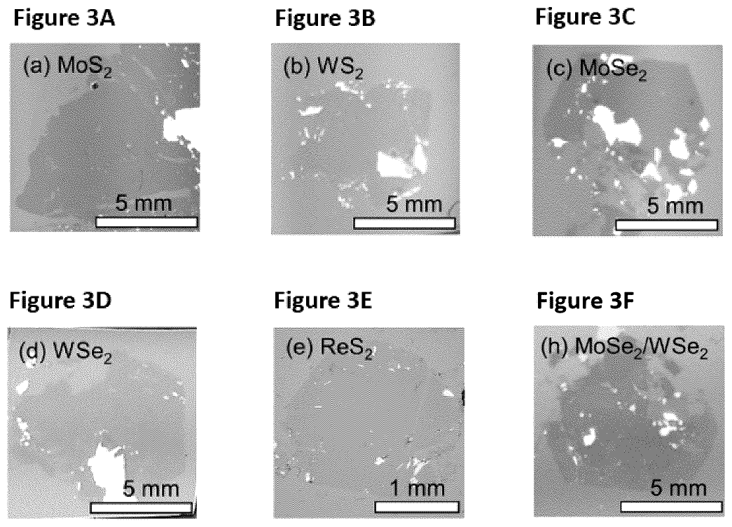

Optical images of the monolayers are shown in FIGS. 3A-3F. Each TMDC sample is dominated by the single crystal monolayer, sometimes with small regions of multilayers near the edges, resulting from the contact of the gold tape to imperfect or non-flat regions on the edges of TMDC bulk crystal.

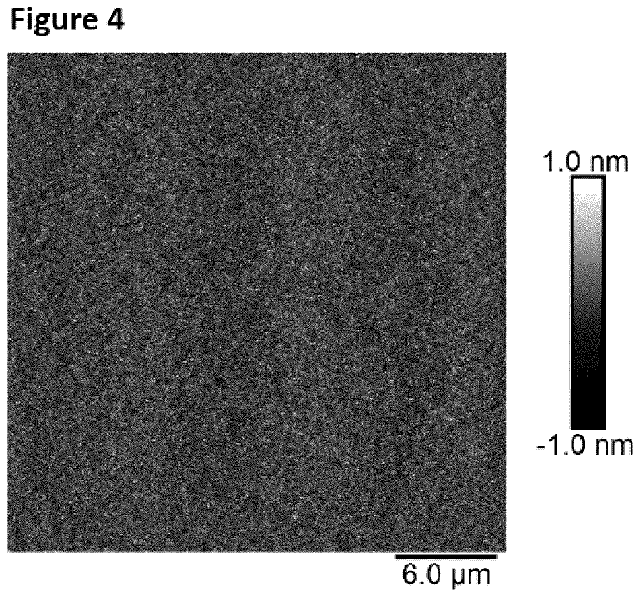

The quality of the large single crystal monolayer is comparable to or slightly better than that of microscopic single crystal monolayers produced from the Scotch tape method, as evidenced in the clean surface characterized by atomic force microscopy (AFM) and the crystal quality characterized by photoluminescence (PL) spectroscopy. AFM image of the TMDC monolayer flakes reveals atomic scale flatness, as shown in FIG. 4 for a MoS₂ monolayer. PL spectroscopy can be particularly sensitive to defects and disorder, as increased peak width is evidence of inhomogeneous broadening (disorder) and reduced intensity indicative of defect-mediated nonradiative recombination.

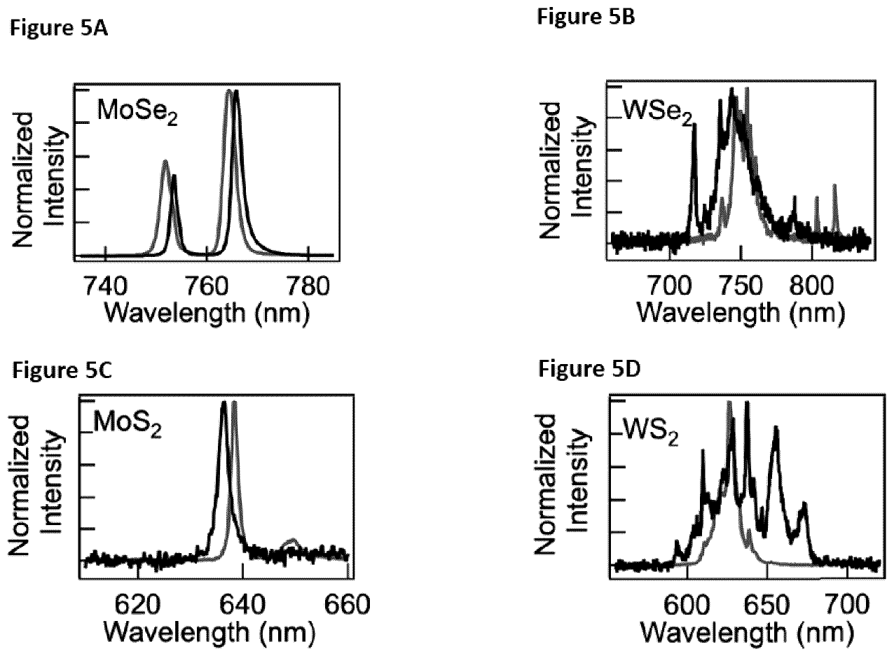

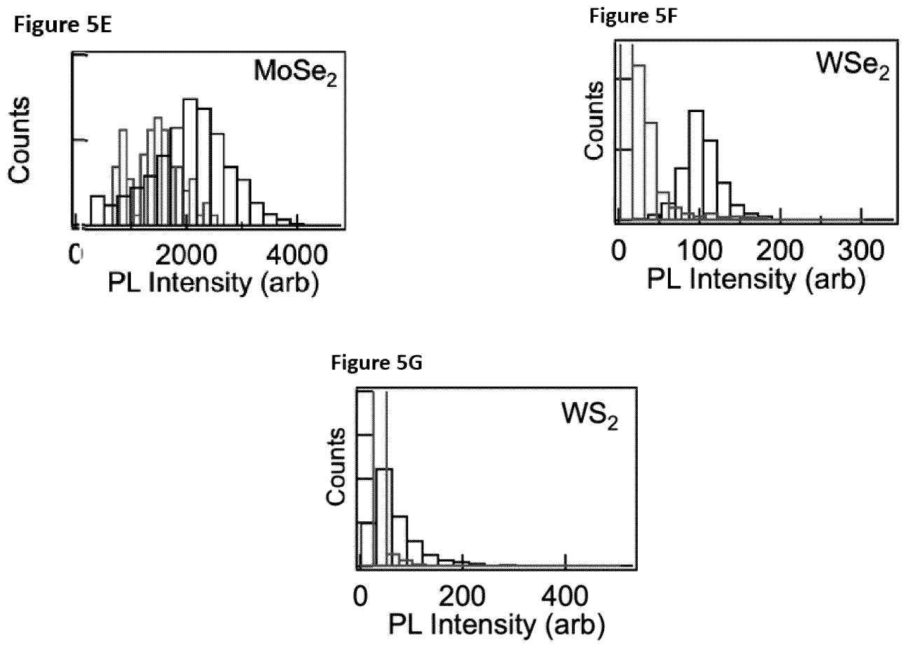

Low temperature PL spectra of the macroscopic TMDC monolayers from the metal tape method disclosed herein and microscopic monolayers from the Scotch tape method can be compared with all monolayers encapsulated in h-BN to eliminate the effect from substrate defects and inhomogeneity as shown in FIGS. 5A-5G. For MoS₂ and MoSe₂, the PL spectra from the two methods are nearly identical. The former is characterized by the dominant A exciton and the latter shows the A exciton and the trion peaks, both nearly independent of the two exfoliation methods. PL image histogram analysis (FIG. 5A-5G) shows that the PL intensities from the macroscopic monolayers are consistent with or slightly higher than those from the standard Scotch tape method. For WS₂ and WSe₂ monolayers, the PL spectra from methods are similarly complex due to the presence of dark excitons and many-body states; however, overall PL intensity in these macroscopic monolayers is still comparable to or slightly higher than those from the Scotch tape method. These results confirm the high quality of the macroscopic TMDC monolayers.

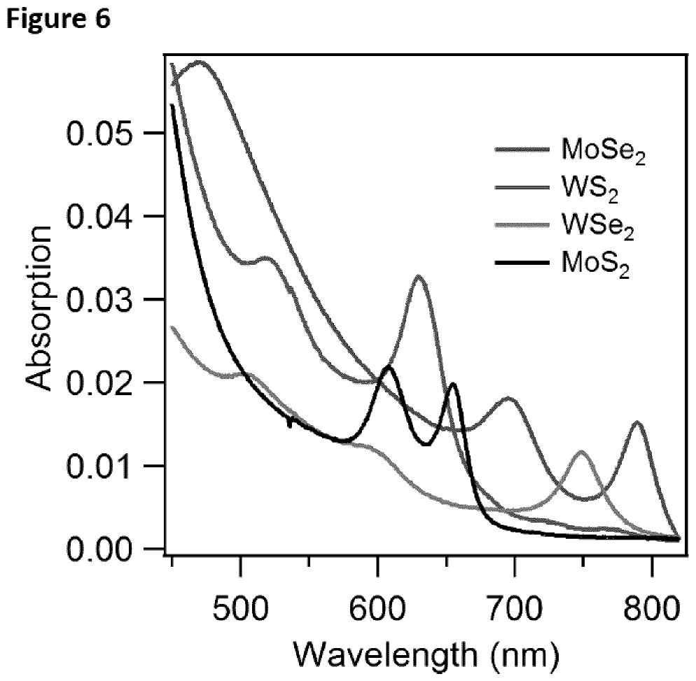

Obtaining macroscopic single crystal monolayers of 2D vdW crystals with high throughput has a broad range of applications, spanning from spectroscopy, to scalable devices, and to the easy assembly of artificial lattices. For example, the macroscopic size of the TMDC monolayers prepared on transparent substrates allows use of a conventional UV-Vis spectrometer to obtain optical absorption spectra of TMDC monolayers (FIG. 6), each featuring the well-known A and B excitons. The effective disassembly of the bulk crystal into individual single crystal monolayers with defined crystal orientation allows reassembly into artificial vdW crystals with desired properties. Specifically, the flexible and flat metal tape can be used as an effective pick-up tool to reassemble higher-order vdW lattices from the macroscopic single crystals. Two examples include: (1) the reassembly of macroscopic TMDC monolayers into an artificial crystal lattice with AA stacking for greatly enhanced nonlinear optical response; and (2) the formation of a macroscopic heterobilayer from two distinct TMDC monolayers.

The first example targets effective engineering of nonlinear optical properties in an ultrathin material. TMDC monolayers, with intrinsically broken inversion symmetry, are known to possess ultra-strong nonlinear susceptibilities as reflected in intense second harmonic generation (SHG). However, TMDC bulk crystals exhibit 2H centro-symmetry; the crystal orientation of neighboring layers is 180° counter-aligned with each other in the so-called AB stacking. Due to cancellation between counter-aligned layers, the SHG response is smaller in few-layer samples, becoming asymptotically negligible for the bulk crystal. Indeed, interference in SHG from individual monolayers in stacked homo- or hetero-bilayers is very sensitive to the alignment angle between the two layers. TMDC bulk crystal can be disassembled into individual monolayers, and the even (or odd) monolayers can be reassembled into artificial crystals.

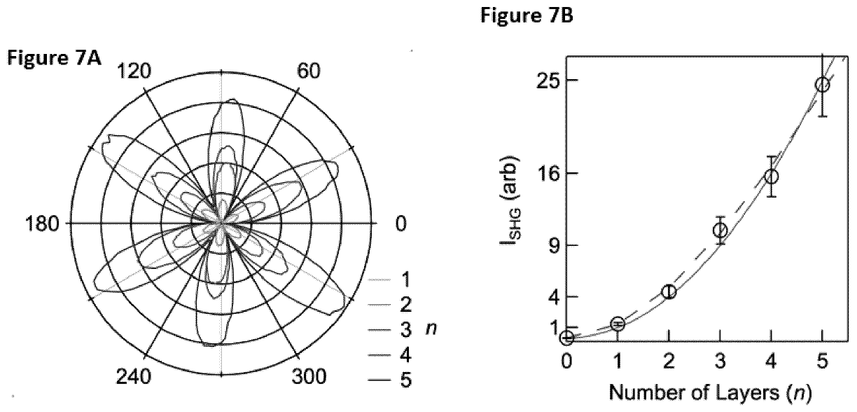

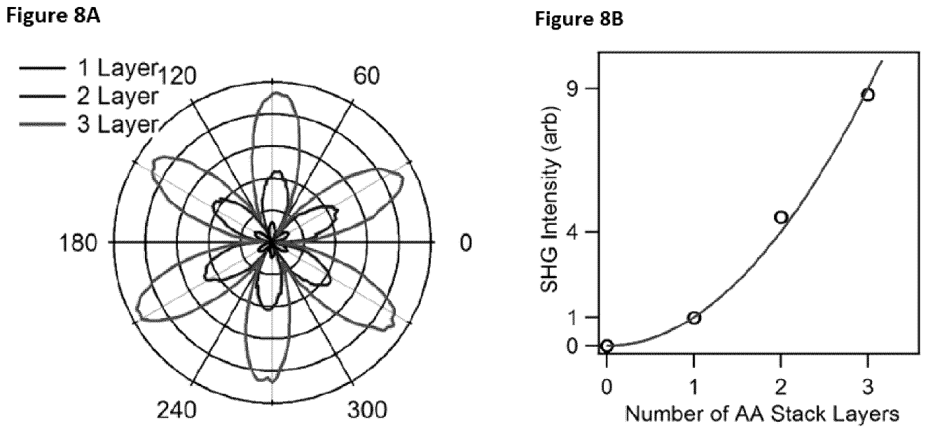

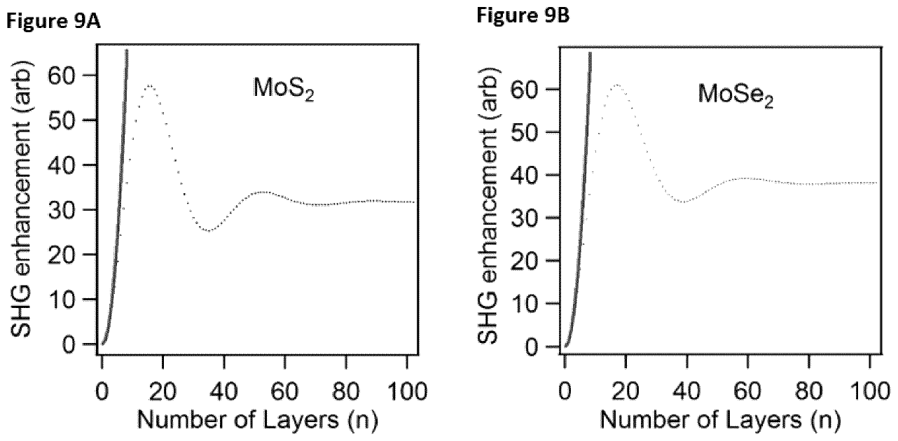

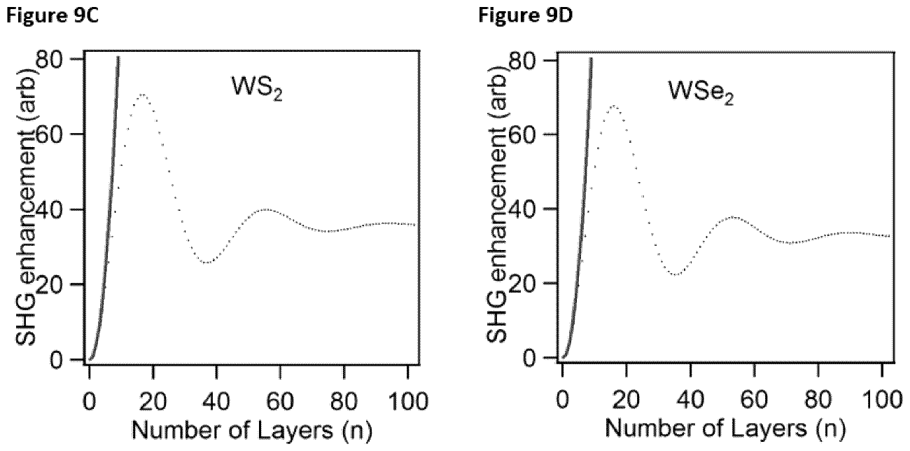

FIG. 7A shows angle-resolved SHG responses from 1-5 layers of an AA-stacked MoSe₂ artificial lattice, with the integrated SHG intensities (/_{sHG}, circles) plotted against the number (n) of the monolayers in FIG. 7B. Similar results for AA stacked MoS₂ are shown in FIGS. 8A-8B. The dashed line in FIG. 7B corresponds to fit which take into account re-absorption and interference of SHG from different layers. At ultrathin thickness, the SHG response is dominated by constructive interference from adjacent layers, close to the ideal limit of a quadratic optical response, iSHG ∝n², the solid curve in FIG. 7B. The close to perfect coherent enhancement benefits from the negligible phase mismatch over nanometer distances. With increasing thickness of the artificial lattice, the increase of coherent response is expected to continue, until 10 s nm when phase mismatch and reabsorption of SHG light become significant, as is shown in FIGS. 9A-9D. While synthesis of 3R phases of TMDC with broken inversion symmetry is possible, the techniques disclosed herein are unrestricted by synthesis and can be used to construct any macroscopic vdW multilayer structures with control in interlayer twist angles and chemical identities. As one indication of the consistency of the artificial lattices from the macroscopic monolayers, FIG. 7 illustrates the SHG response from the MoSe₂/WSe₂ heterobilayer at five randomly picked spots. The orientation of the artificial lattice is unchanged from spot-to-spot with an angular resolution of ±0.5°. The SHG intensity variation is within ±15%, which can be due to small changes in optical alignment as the sample is moved macroscopically under the microscope.

The second example is the creation of heterobilayers with controlled twist angle from two macroscopic single crystal monolayers. By engineering angular and/or lattice mismatch, vdW bilayers constructed from the same or different single crystal 2D monolayers have been shown to exhibit a range of quantum phenomena, but only on μm scale samples from the Scotch tape method. This example illustrate vdW bilayers constructed from the same or different single crystal 2D monolayers on the cm macroscopic scale.

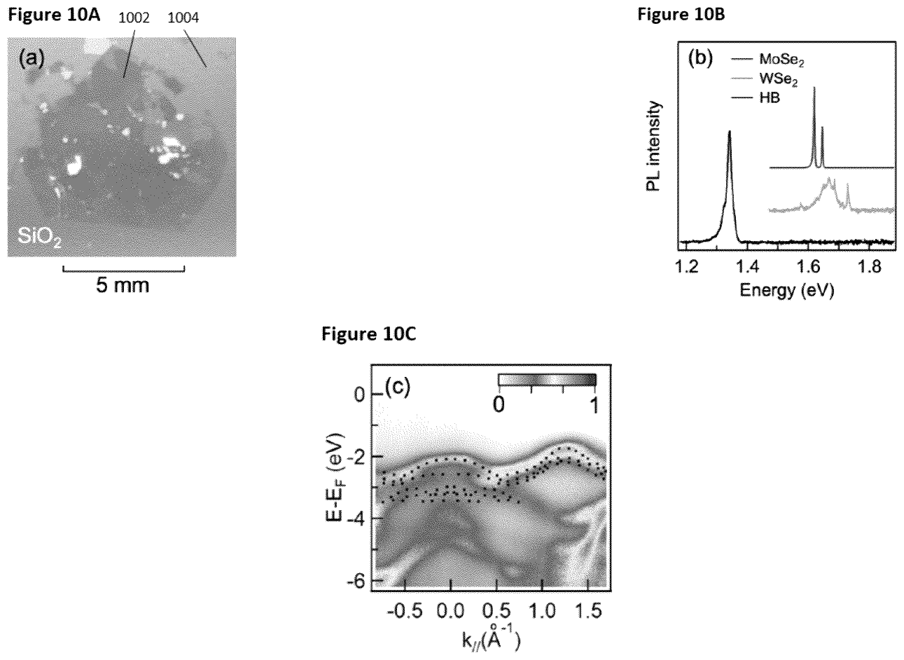

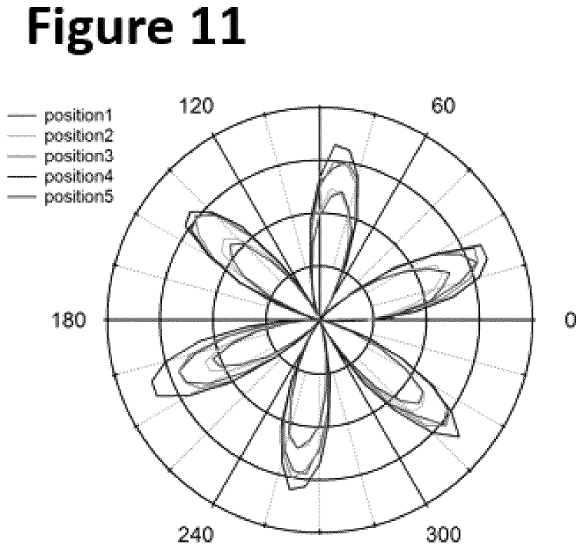

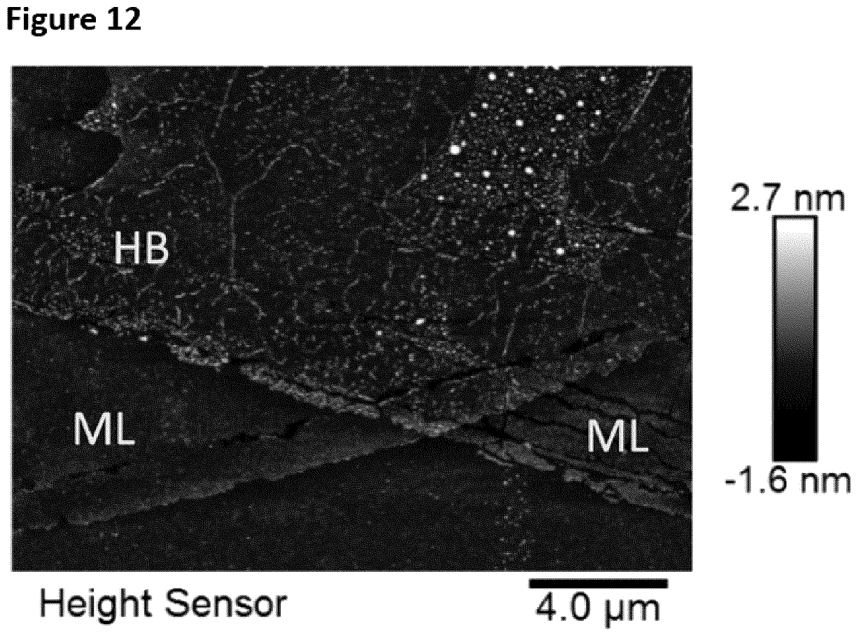

A technological application lies in the generation of bilayer structures at macroscopic dimensions. Using two monolayers of MoSe₂ and WSe₂, a MoSe₂/WSe₂ single crystal heterobilayer 402 was fabricated, as is shown in optical image in FIG. 10A, with lateral dimensions of ˜4 mm and with twist angle of ΔΘ=3.0±0.5°. AFM imaging on part of the macroscopic structure identifies the heterobilayer 402 with a high degree of flatness (FIG. 12).

FIG. 10B illustrates PL spectra of interlayer exciton in a heterobilayer compared to MoSe₂ and WSe₂ monolayers. The large size of the single crystal heterobilayer on a dielectric substrate (SiO₂) 404 allows mapping out the band structure using angle resolved photoemission spectroscopy (ARPES) using a conventional setup with hemispherical electron energy analyzer, without microscopic capabilities (μ-ARPES). The ARPES spectrum determined in the Γ-K direction is in excellent agreement with theoretical calculations (FIG. 10C). Low temperature PL measurement of BN encapsulated heterobilayer stack reveals the dominant radiative recombination from the charge separated interlayer exciton (FIG. 10C), in agreement with interlayer excitons in MoSe₂/WSe₂ heterobilayers with microscopic dimensions fabricated from the Scotch-tape method. Moreover, the intralayer excitons from constituent monolayers in the heterobilayer sample are completely quenched, verifying the high quality of the MoSe₂/WSe₂ interface.

### Methods

The present disclosure also provides methods for preparing vdW crystals. In certain embodiments, a 150 nm thickness gold layer can be deposited onto flat silicon substrate (NOVA Electronic Materials LLC, p type doped) with e-beam evaporation (Angstrom Engineering EvoVac Multi-Process thin film deposition system). A layer of polyvinylpyrrolidone (PVP) solution (Sigma Aldrich, mw 40000, 10% wt in ethanol/acetonitrile wt 1/1) can be spin-coated on the top of the gold film and cured at 150° C. for 5 min as a sacrificial layer to prevent tape residue contamination. The prepared PVP and gold layers can be picked up with thermal release tape (semiconductor corp. release temperature 90° C.), revealing an ultra-flat, clean, and fresh gold surface, i.e., the gold tape. The gold tape can be gently pressed onto a freshly cleaved bulk vdW crystal, including a MoS₂ natural single crystal (SPI Supplies), WS₂, MoSe₂, WSe₂, and ReS₂ single crystals (HQ graphene), and the MoSe₂ and WSe₂ single crystals from a flux-growth method with significantly reduced defect density. As the tape is lifted off the surface, it can carry the PVP and gold layers with a monolayer 2D crystal attached to gold surface, and can further transferred onto the desired substrate.

The thermal release tape can be removed by heating at 130° C. The PVP layer can be removed by dissolving in deionized (DI) water for 2 hours. The sample on the substrate covered by gold can be rinsed with acetone and cleaned by O₂ plasma for 3 min to remove any remaining polymer residues. The gold layer can be dissolved in a KI/I₂ gold etchant solution (2.5 g I₂ and 10 g KI in 100 ml DI water. Iodine, 99.99%, Alfa Aesar; potassium iodide, 99.9%, Alfa Aesar). The monolayer can be rinsed with DI water and isopropanol, and dried with N₂. For stacking of multiple AA stacks, a collection of single crystal monolayers from the same single crystal can be prepared on SiO₂/Si substrates (SiO₂ thickness=285 nm) with known sequences of odd-even order. An ultra-flat gold tape, freshly peeled off the Si templating surface, can be used to pick up only even or odd monolayers sequentially with angular alignment, ΔΘ=0.0±0.5°. The SHG measurements can be performed on the stacked monolayers on gold after each pick up. For stacking of macroscopic heterobilayer, a freshly prepared gold tape can be used to pick up a MoSe₂ monolayer and then can be pressed onto another freshly prepared WSe₂ monolayer on the SiO₂/Si substrate with pre-determined alignment angle, followed by the same rinsing and etching procedure.

Thin BN flakes for encapsulation can be exfoliated with scotch tape onto the SiO₂/Si surface (SiO₂ thickness 285 nm). The TMDC monolayers are prepared either from the gold tape technique or traditional scotch tape exfoliation onto the SiO₂/Si substrate. A film of polypropylene carbonate (“PPC”) can be prepared on top of a small polydimenthylsiloxane (PDMS) stamp taped on a glass slide. The glass slide can be inverted and fixed on a transfer stage with objective lens, and can be used to sequentially pick up the flakes with controlled contact point. Lifting of the first BN flake can be achieved by controlled expansion of PPC through increasing and decreasing temperature near 40° C. After the first BN flake is picked up to PPC, the process can be repeated to pick up the TMD monolayer and the last layer of BN. The thin flakes can be more adhesive to BN than to SiO₂/Si substrate, permitting encapsulation of BN/TMD/BN stacks on PPC surface. The stack can be further transferred onto desired substrate by pushing the PPC onto the substrate and heating substrate to 90-120° C. to melt PPC, allowing the stack to stay on the substrate while the glass slide and PDMS are removed.

The SHG measurements can be performed at room temperature on an inverted microscope (Olympus IX73, with 100×objective). The pump 800 nm for SHG can be generated from an ultrafast Ti:Sapphire oscillator (SpectraPhysics Tsunami, pumped by Sprout D, 5W, Lighthouse Photonics), and reflected off a 650 nm short-pass dichroic mirror, and is focused onto the sample with a 100×objective. The SHG of the sample can transmit through the 650 nm short-pass dichroic mirror and a 400 nm bandpass filter before it is collected with a photomultiplier tube. The signal can be amplified and detected with a photon counter. The polarization for both the input laser and the collection path can be rotated simultaneously relative to the sample, by rotating a half waveplate between the objective and the dichroic mirror, intersecting both the excitation and collection path. Therefore, the polarization response of SHG can be equal to rotating the sample, giving rise to a 6-fold symmetry.

For ARPES measurements, the TMDC heterostructure on SiO₂/Si substrate can be transferred to an ultrahigh vacuum chamber (−10⁻¹⁰ Torr) and annealed at 200° C. for 4 h via direct current heating to remove residual contaminants. A gold contact can be placed on the side for grounding. The ARPES measurements can be carried out in the ultrahigh vacuum at room temperature. For photoionization, a 22 eV extreme UV radiation can be obtained from high harmonic generation (HHG) from 400 nm input laser light in Kr gas. The 400 nm light can come from the second harmonic of the output of a regenerative Ti:Sapphire amplifier (Coherent Legend Elite Duo HE+, 10 kHz, 35 fs). HHG can be generated in a modified KMLabs XUUS4 high harmonics systems. The kinetic energy of the photoemitted electrons can be measured on a hemispherical electron energy analyzer equipped with a 2D delay line detector (SPECS Phoibos-100).

The TMDC heterobilayer and monolayer samples on SiO₂/Si substrates can be placed in a liquid helium recirculating optical cryostat (Montana Instruments Fusion/X-Plane) at 4 K in vacuum (<10−6 torr). The incident laser beam (532 nm, CW) can be focused on the sample by a 100×x, NA 0.75 objective (Zeiss LD EC Epiplan-Neofluar 100×/0.75 HD DIC M27) to a diffraction limited spot. The excitation power can be approximately 80 uW, measured by a calibrated power meter (Ophir StarLite). PL emissions from the sample plane can be imaged with a home-built scanning confocal microscope system with a Galvo-Galvo scanner (Thorlabs, GVSO12/M). The photoluminescence can be collected by the same objective, focused into a spectrograph (Princeton Instruments, IsoPlane 160) and detected by a liquid-N2 cooled InGaAs photodiode array (Princeton Instruments PyLoNIR) within the desired wavelengths.

The wave propagation of 400 nm and 800 nm light in the SHG process can be calculated with the reported optical constants, taking into the account a) absorption of 400 nm and 800 nm as they propagate through the thin layer crystal and b) interference of 400 nm generated from each layer. Simulated results are displayed in FIGS. 9A-9D. The red curve shows the quadratic response for coherent interference enhancement assuming zero phase delay for SHG from all layers. At few layer numbers, the simulation is close to the quadratic response. With increasing thickness of the AA stacked lattice, phase mismatch and reabsorption of SHG light become significant, and the response deviates from quadratic coherent enhancement. The peak of the enhancement is predicted to be approximately 60-fold for MoS₂ AA stacked layers, which is consistent with a SHG enhancement from different thickness of 3R phase MoS₂, which has non-centrosymmetric with AA stack interlayer alignment.

The foregoing merely illustrates the principles of the present disclosure. Various modifications and alterations to the described embodiments will be apparent to those skilled in the art in view of the teachings herein. It will thus be appreciated that those skilled in the art will be able to devise numerous techniques which, although not explicitly described herein, embody the principles of the present disclosure and are thus within its spirit and scope.

1. A method for generating one or more single crystal monolayers from two-dimensional van der Waals crystals, comprising:
providing a bulk material comprising a plurality of van der Waals crystal layers; and
exfoliating one or more single crystal monolayers of van der Waals crystal from the bulk material by applying an flexible and flat metal tape to a surface of the bulk material;
wherein the flexible and flat metal tape has a surface root-mean-square roughness of less than 2 nm.

2. The method of claim 1, wherein the flexible and flat metal tape has a surface root-mean-square roughness of less than 1 nm.

3. The method of claim 1, wherein the metal comprises air-stable metals, including coinage metals.

4. The method of claim 4, wherein the metal is selected from the group consisting of Gold, Silver, Platinum, Palladium, Coper, Nickel, and Chromium.

5. The method of claim 1, further comprising assembling the one or more single crystal monolayers into an artificial lattice.

6. The method of claim 1, wherein the exfoliating comprises:
pressing the flexible and flat metal tape on to a surface of the bulk material; and
removing the flexible and flat metal tape off the surface to form a single crystal monolayer on the metal surface.

7. The method of claim 6, wherein the flexible and flat metal tape comprises a thermal release tape having a layer comprising a soluble protection layer and a metal layer, and wherein the removing further comprises:
heating the tape;
dissolving the protection layer in a solvent; and
dissolving the metal layer in an etchant solution.

8. A method for manufacturing flexible and flat metal tape for generating one or more single crystal monolayers from two-dimensional van der Waals crystals, comprising:
forming a layer of metal having a surface root-mean-square roughness of less than 2 nm on an ultra-flat wafer;
depositing a soluble polymer on the metal layer; and
removing the metal layer and the polymer layer from the ultra-flat wafer.

9. The method of claim 8, wherein the forming comprises depositing a metal having a surface root-mean-square roughness of less than 1 nm.

10. The method of claim 8, wherein the forming comprises depositing a metal having a surface root-mean-square roughness in the range of about 0.3 to about 0.5 nm.

11. The method of claim 8, wherein the metal is selected from the group consisting of Gold, Silver, Platinum, Palladium, Coper, Nickel, and Chromium.

12. The method of claim 8, wherein the ultra-flat wafer is selected from the group consisting of a silicon wafer, a germanium wafer, a mica wafer, a single crystal semiconductor wafer, and a super-polished surface.

13. The method of claim 8, wherein the depositing comprises coating the metal layer with the polymer.

14. The method of claim 8, wherein the protection layer comprises a polymer adapted to be soluble in water or an organic solvent.

15. The method of claim 8, wherein the protection layer is selected from the group consisting of a water-soluble polyvinylpyrrolidone or an organic solvent-soluble polypropylene carbonate or polycarbonate or polycaprolactone.

16. A composition for creating a macroscopic artificial lattice, comprising:
two or more macroscopic single crystal monolayers adapted from a bulk van der Waals crystal;
wherein the single crystal monolayers are configured for assembly into an artificial lattice based on one or more properties.

17. The composition of claim 16, wherein the one or more properties includes nonlinear optical properties.

18. The composition of claim 16, wherein a first of the two or more macroscopic single crystal monolayers has an orientation difference from a second of the two or more macroscopic single crystal monolayers, wherein the first and single crystal monolayers are adapted for reassembly into an artificial lattice.

19. The composition of claim 18, wherein the orientation difference is about 180 degrees.

20. The composition of claim 16, wherein a first of the two or more macroscopic single crystal monolayers and a second of the two or more macroscopic single crystal monolayers are configured to create one of a single crystal heterobilayer or a single crystal heteromultilayer.

21. The composition of claim 16, wherein the two or more macroscopic single crystal monolayers are transition-metal dichalcogenide monolayers.

22. The composition of claim 16, wherein the transition-metal dichalcogenide is chosen from the group consisting of MoS₂, WS₂, MoSe₂, WS₂, WSe₂, MoTe₂, and MoS₂.

23. The composition of claim 17, wherein the non-linear optical properties comprise second harmonic generation.

24. The composition of claim 20, wherein a configuration of the monolayers includes an angular and/or lattice mismatch.

25. The Composition of claim 20, wherein the single crystal heterobilayer or a single crystal heteromultilayer comprise transition-metal dichalcogenide monolayers.

26. The Composition of claim 25, wherein the transition-metal dichalcogenide is chosen from the group consisting of MoS₂, WS₂, MoSe₂, WS₂, WSe₂, MoTe₂, and MoS₂.

27. The Composition of claim 26, wherein the transition-metal dichalcogenide of the first of the two or more macroscopic single crystal monolayers and of the second of the two or more macroscopic single crystal monolayers are different.

28. The Composition of claim 27, wherein the transition-metal dichalcogenide of the first of the two or more macroscopic single crystal monolayers and of the second of the two or more macroscopic single crystal monolayers are chosen from MoSe₂ and WSe₂ monolayers.
